(19) United States
(12) Patent Application Publication
(10) Pub. No.: US 2025/0351352 A1
(43) Pub. Date: Nov. 13, 2025

(54) SEMICONDUCTOR DEVICE AND MANUFACTURING METHOD OF A SEMICONDUCTOR DEVICE

(71) Applicant: SK hynix Inc., Icheon-si Gyeonggi-do (KR)

(72) Inventor: Nam Jae LEE, Icheon-si Gyeonggi-do (KR)

(73) Assignee: SK hynix Inc., Icheon-si Gyeonggi-do (KR)

(21) Appl. No.: 19/272,810

(22) Filed: Jul. 17, 2025

Related U.S. Application Data
(62) Division of application No. 17/241,729, filed on Apr. 27, 2021.

(30) Foreign Application Priority Data
Oct. 23, 2020 (KR) 10-2020-0138375

(51) Int. Cl. H10B 43/27; H10B 41/27; H10B 41/43

(52) U.S. Cl. CPC H10B 43/27; H10B 41/27; H10B 41/43

(57) ABSTRACT

A semiconductor device includes a first insulating layer, a first bonding pad in the first insulating layer, a second insulating layer in contact with the first insulating layer, and a second bonding pad in the second insulating layer. The first bonding pad includes a first conductive layer and a first barrier layer surrounding the first conductive layer, and the second bonding pad includes a second conductive layer and a second barrier layer surrounding the second conductive layer. The second barrier layer is in contact with the first conductive layer. The second conductive layer is spaced apart from the first conductive layer. The first conductive layer includes a metal material which is different from a metal material included in the second conductive layer. The first and second barrier layers each include at least one of titanium and tantalum.

### CROSS-REFERENCE TO RELATED APPLICATION

The present application is a divisional application of U.S. patent application Ser. No. 17/241,729, filed on Apr. 27, 2021, which claims priority under 35 U.S.C. § 119 (a) to Korean patent application number 10-2020-0138375, filed on Oct. 23, 2020, in the Korean Intellectual Property Office, the entire contents of which applications are incorporated herein by reference.

### BACKGROUND

### 1. Technical Field

The present disclosure generally relates to a semiconductor device and a manufacturing method of a semiconductor device, and more particularly, to a three-dimensional semiconductor device and a manufacturing method of a three-dimensional semiconductor device.

### 2. Related Art

A semiconductor device includes memory cells capable of storing data. A three-dimensional semiconductor device includes three-dimensionally arranged memory cells, so that a two-dimensional footprint occupied by the memory cells on a substrate can be reduced.

In order to improve the degree of integration of the three-dimensional semiconductor device, a number of stacked memory cells may be increased. The operational reliability of the three-dimensional semiconductor device, however, may deteriorate as the number of stacked memory cells continues to increase.

### SUMMARY

Some embodiments are directed to a semiconductor device and a manufacturing method of a semiconductor device, which can minimize process cost and process limitation for forming bonding pads connected to a channel layer.

In accordance with an embodiment of the present disclosure, a semiconductor device includes: a first insulating layer; a first bonding pad in the first insulating layer; a second insulating layer in contact with the first insulating layer; and a second bonding pad in the second insulating layer. The first bonding pad includes a first conductive layer and a first barrier layer surrounding the first conductive layer. The second bonding pad includes a second conductive layer and a second barrier layer surrounding the second conductive layer. The second barrier layer is in contact with the first conductive layer. The second conductive layer is spaced apart from the first conductive layer. The first conductive layer includes a metal material which is different from a metal material included in the second conductive layer. The first and second barrier layers each include at least one of titanium and tantalum.

In accordance with another embodiment of the present disclosure, a semiconductor device includes: a peripheral transistor; a first connection conductor connected to the peripheral transistor; a first bonding pad connected to the first connection conductor; a second bonding pad connected to the first bonding pad; a second connection conductor connected to the second bonding pad; a channel layer connected to the second connection conductor; and a stack structure penetrated by the channel layer. The first bonding pad includes a first conductive layer and a first barrier layer surrounding the first conductive layer. The second bonding pad includes a second conductive layer and a second barrier layer surrounding the second conductive layer. The first conductive layer includes copper, and the second conductive layer includes tungsten.

In accordance with still another embodiment of the present disclosure, a semiconductor device includes: a first stack structure including first conductive patterns and first insulating patterns, which are alternately stacked; a first channel layer penetrating the first stack structure; a first connection conductor connected to the first channel layer; a first bonding pad connected to the first connection conductor; a second bonding pad connected to the first bonding pad; a second connection conductor connected to the second bonding pad; a second stack structure including second conductive patterns and second insulating patterns, which are alternately stacked; and a second channel layer penetrating the second stack structure, the second channel layer being connected to the second connection conductor. The first bonding pad includes a first conductive layer and a first barrier layer surrounding the first conductive layer. The second bonding pad includes a second conductive layer and a second barrier layer surrounding the second conductive layer. The first conductive layer includes copper, and the second conductive layer includes tungsten.

In accordance with still another embodiment of the present disclosure, a method of manufacturing a semiconductor device includes: forming a first substrate; forming a first connection structure including a first bonding pad on the first substrate; forming a first semiconductor structure on the first connection structure, wherein the first semiconductor structure includes a first channel layer electrically connected to the first bonding pad and a first stack structure surrounding the first channel layer; forming a second connection structure including a second bonding pad on the first semiconductor structure, wherein the second bonding pad is electrically connected to the first channel layer; exposing the first bonding pad by removing the first substrate; forming a third connection structure including a third bonding pad; and bonding the first bonding pad and the third bonding pad to each other.

### BRIEF DESCRIPTION OF THE DRAWINGS

Example embodiments will now be described more fully hereinafter with reference to the accompanying drawings; however, they may be embodied in different forms and should not be construed as being limited to the embodiments set forth herein. Rather, these embodiments are provided so that this disclosure will be enabling, and will convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1A is a sectional view of a semiconductor device in accordance with an embodiment of the present disclosure.

FIG. 1B is an enlarged view of region A shown in FIG. 1A.

FIG. 1C is an enlarged view of region B shown in FIG. 1A.

FIGS. 2A, 2B, 2C, 2D, 2E, 2F, 2G, 2H, 2I, 2J, 2K, 2L, and 2M are sectional views illustrating a manufacturing method of the semiconductor device shown in FIGS. 1A to 1C.

FIG. 3 is a block diagram illustrating a configuration of a memory system in accordance with an embodiment of the present disclosure.

FIG. 4 is a block diagram illustrating a configuration of a computing system in accordance with an embodiment of the present disclosure.

### DETAILED DESCRIPTION

The specific structural or functional description disclosed herein is merely illustrative for the purpose of describing embodiments according to the concept of the present disclosure. The embodiments can be implemented in various forms and should not be construed as being limited to the embodiments set forth herein.

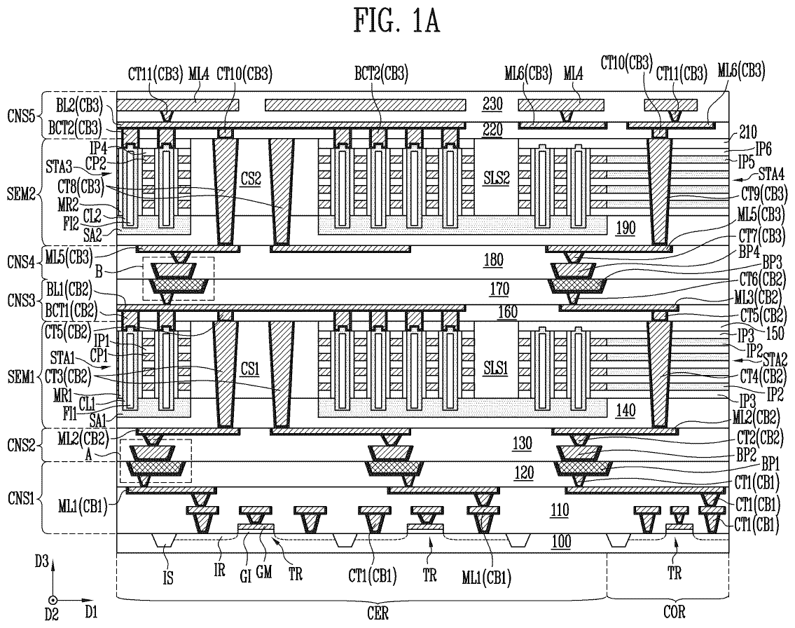

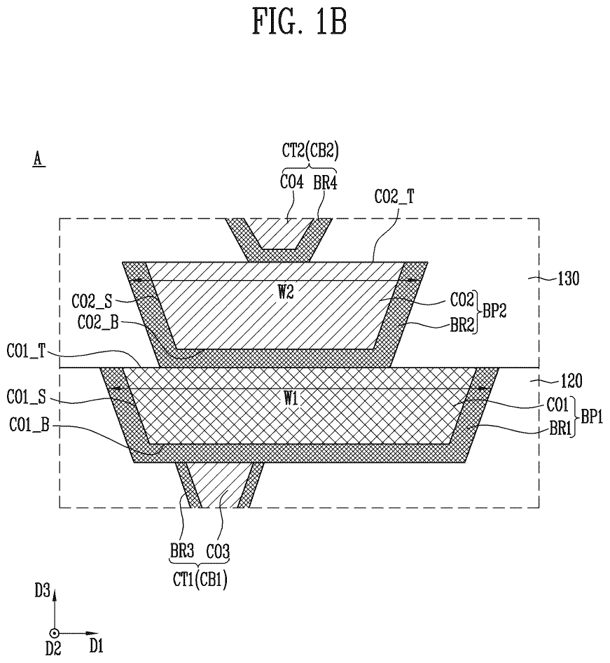

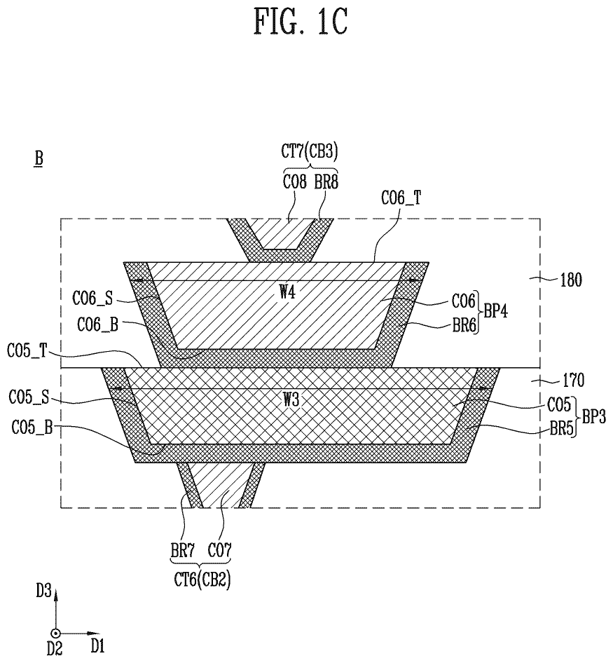

FIG. 1A is a sectional view of a semiconductor device in accordance with an embodiment of the present disclosure. FIG. 1B is an enlarged view of region A shown in FIG. 1A. FIG. 1C is an enlarged view of region B shown in FIG. 1A.

Referring to FIG. 1A, the semiconductor device may include a cell region CER and a connection region COR. The cell region CER and the connection region COR may be regions divided from the viewpoint of a plane defined by a first direction D1 and a second direction D2. The first direction D1 and the second direction D2 may intersect each other. In an example, the first direction D1 and the second direction D2 may be orthogonal to each other.

The semiconductor device may include a first substrate 100. The first substrate 100 may have the shape of a plate extending along a plane defined by the first direction D1 and the second direction D2. The first substrate 100 may extend from the cell region CER and the connection region COR. In an example, the first substrate 100 may extend in the first direction D1. The first substrate 100 may include a semiconductor material. In an example, the first substrate 100 may include silicon.

A first connection structure CNS1 may be provided on the first substrate 100. The first connection structure CNS1 may include a first insulating layer 110, a second insulating layer 120, first connection conductors CB1, and first bonding pads BP1.

The first insulating layer 110 may cover the first substrate 100. The first insulating layer 110 may include an insulating material. In an example, the first insulating layer 110 may include oxide or nitride.

The second insulating layer 120 may cover the first insulating layer 110. The second insulating layer 120 may include an insulating material. In an example, the second insulating layer 120 may include oxide or nitride.

The first connection conductors CB1 may be provided in the first and second insulating layers 110 and 120. The first connection conductors CB1 may include first contacts CT1 and first lines ML1. The first contacts CT1 and the first lines ML1 may be connected to each other. Each of the first contacts CT1 and the first lines ML1 may include a conductive layer and a barrier layer. In an example, the conductive layer may include copper, aluminum, or tungsten. In an example, the barrier layer may include titanium, tantalum, titanium nitride, or tantalum nitride.

The first bonding pads BP1 may be provided in the second insulating layer 120. The first bonding pad BP1 may be connected to the first contact CT1 of the first connection conductors CB1. The first bonding pad BP1 may be in contact with the first contact CT1 of the first connection conductors CB1. The first bonding pad BP1 will be described in detail with reference to FIG. 1B.

Peripheral transistors TR may be provided between the first substrate 100 and the first connection structure CNS1. The peripheral transistors TR may constitute a peripheral circuit of the semiconductor device, or be transistors connected to the peripheral circuit.

Each of the peripheral transistors TR may include impurity regions IR, a gate insulating layer GI, and a gate electrode GM. The impurity regions IR may be formed by doping an impurity into the substrate 100. The impurity region IR may be connected to the first contact CT1 of the first connection conductors CB1. The impurity region IR may be in contact with the first contact CT1 of the first connection conductors CB1.

The gate insulating layer GI may include insulating material. In an example, the gate insulating layer GI may include oxide. The gate electrode GM may be connected to the first contact CT1 of the first connection conductors CB1. The gate electrode GM may be in contact with the first contact CT1 of the first connection conductors CB1. The gate electrode GM may include a conductive material.

Isolation layers IS may be provided in the first substrate 100. The isolation layers IS may electrically isolate the peripheral transistors TR from each other. The isolation layers IS may include an insulating material. In an example, the isolation layers IS may include oxide.

A second connection structure CNS2 may be provided on the first connection structure CNS1. The second connection structure CNS2 may include a third insulating layer 130 and second bonding pads BP2.

The third insulating layer 130 may cover the second insulating layer 120. The third insulating layer 130 may include an insulating material. In an example, the third insulating layer 130 may include oxide or nitride.

The second bonding pads BP2 may be provided in the third insulating layer 130. The second bonding pad BP2 may be connected to the first bonding pad BP1. The second bonding pad BP2 may be in contact with the first bonding pad BP1. The second bonding pad BP2 will be described in detail with reference to FIG. 1B.

A first semiconductor structure SEM1 may be provided on the second connection structure CNS2. The first semiconductor structure SEM1 may include a fourth insulating layer 140, first source layers SA1, a first stack structure STA1, a second stack structure STA2, a first contact insulating structure CS1, a first slit structure SLS1, first channel layers CL1, first memory layers MR1, first filling layers FI1, and a fifth insulating layer 150.

The fourth insulating layer 140 may cover the third insulating layer 130. The fourth insulating layer 140 may include an insulating material. In an example, the fourth insulating layer 140 may include oxide or nitride.

The first source layers SA1 may be provided in the fourth insulating layer 140. The first source layer SA1 may have the shape of a plate extending along a plane defined by the first direction D1 and the second direction D2. The first source layers SA1 may be spaced apart from each other in the first direction D1. A portion of the fourth insulating layer 140 may be interposed between the first source layers SA1 spaced apart from each other. The first source layer SA1 may include a conductive material. In an example, the first source layer SA1 may include poly-silicon. The first source layer SA1 may be provided in the cell region CER.

The first stack structure STA1 may be provided on the first source layers SA1. The first stack structure STA1 may include first conductive patterns CP1 and first insulating patterns IP1, which are alternately stacked in a third direction D3. The third direction D3 may intersect the first direction D1 and the second direction D2. In an example, the third direction D3 may be orthogonal to the first direction D1 and the second direction D2. The first conductive patterns CP1 may be used as word lines or select lines of the semiconductor device. The first conductive patterns CP1 may include a conductive material. The first insulating patterns IP1 may include an insulating material. In an example, the first insulating patterns IP1 may include oxide. The first stack structure STA1 may be provided in the cell region CER.

The first memory layers MR1, the first channel layers CL1, and the first filling layers FI1 may penetrate the first stack structure STA1. The first memory layers MR1, the first channel layers CL1, and the first filling layers FI1 may extend in the third direction D3. The first channel layer CL1 may surround the first filling layer FI1, and the first memory layer MR1 may surround the first channel layer CL1. The first channel layers CL1 may be in contact with the first source layer SA1.

The first filling layer FI1 may include an insulating material. In an example, the first filling layer FI1 may include oxide. The first channel layer CL1 may include a semiconductor material. In an example, the first channel layer CL1 may include poly-silicon. The first memory layer MR1 may include a tunnel insulating layer surrounding the first channel layer CL1, a data storage layer surrounding the tunnel insulating layer, and a blocking layer surrounding the data storage layer. The tunnel insulating layer may include a material through which charges can tunnel. In an example, the tunnel insulating layer may include oxide. In an embodiment, the data storage layer may include a material in which charges can be trapped. In an example, the data storage layer may include nitride. In another embodiment, the data storage layer may include various materials according to a data storage method. In an example, the data storage layer may include silicon, a phase change material, or nano dots. The blocking layer may include a material capable of blocking movement of charges. In an example, the blocking layer may include oxide.

The second stack structure STA2 may be provided on the fourth insulating layer 140. The second stack structure STA2 may be provided at substantially the same level as the first stack structure STA1. The second stack structure STA2 may include second insulating patterns IP2 and third insulating patterns IP3, which are alternately stacked in the third direction D3. The second insulating patterns IP2 of the second stack structure STA2 may be disposed at substantially the same level as the first conductive patterns CP1 of the first stack structure STA1. The second insulating patterns IP2 may include an insulating material. In an example, the second insulating patterns IP2 may include nitride. The third insulating patterns IP3 of the second stack structure STA2 may be disposed at substantially the same level as the first insulating patterns IP1 of the first stack structure STA1. The third insulating patterns IP3 of the second stack structure STA2 may include the same material as the first insulating patterns IP1 of the first stack structure STA1. In an example, the third insulating patterns IP3 may include oxide. The third insulating patterns IP3 of the second stack structure STA2 and the first insulating patterns IP1 of the first stack structure STA1 may be continuously formed without any boundary. The second stack structure STA2 may be provided in the connection region COR.

The first and second bonding pads BP1 and BP2 may be provided between the first and second stack structures STA1 and STA2 and the peripheral transistors TR. The peripheral transistors TR may be provided under the first and second bonding pads BP1 and BP2. The first and second stack structures STA1 and STA2 may be provided above the first and second bonding pads BP1 and BP2.

The fifth insulating layer 150 may be provided, which covers the first stack structure STA1 and the second stack structure STA2. The fifth insulating layer 150 may include an insulating material. In an example, the fifth insulating layer 150 may include oxide or nitride.

The first contact insulating structure CS1 may have the shape of a slit extending in the second direction D2 and the third direction D3. The first contact insulating structure CS1 may penetrate the fifth insulating layer 150 and the first stack structure STA1 in the third direction D3. A bottom surface of the first contact insulating structure CS1 may be in contact with a top surface of the fourth insulating layer 140. The first contact insulating structure CS1 may be disposed between the first source layers SA1. The first contact insulating structure CS1 may include an insulating material. In an example, the first contact insulating structure CS1 may include oxide or nitride.

The first slit structure SLS1 may have the shape of a slit extending in the second direction D2 and the third direction D3. The first slit structure SLS1 may penetrate the fifth insulating layer 150 and the first stack structure STA1 in the third direction D3. A bottom surface of the first slit structure SLS1 may be in contact with a top surface of the first source layer SA1. The first slit structure SLS1 may include an insulating material. In an example, the first slit structure SLS1 may include oxide or nitride.

A third connection structure CNS3 may be provided on the first semiconductor structure SEM1. The third connection structure CNS3 may include a sixth insulating layer 160, a seventh insulating layer 170, and third bonding pads BP3.

The sixth insulating layer 160 may cover the fifth insulating layer 150. The sixth insulating layer 160 may cover a top surface of the first contact insulating structure CS1 and a top surface of the first slit structure SLS1. The sixth insulating layer 160 may include an insulating material. In an example, the sixth insulating layer 160 may include oxide or nitride.

The seventh insulating layer 170 may cover the sixth insulating layer 160. The seventh insulating layer 170 may include an insulating material. In an example, the seventh insulating layer 170 may include oxide or nitride.

The third bonding pads BP3 may be provided in the seventh insulating layer 170. The third bonding pad BP3 will be described in detail with reference to FIG. 1C.

Second connection conductors CB2 may be provided, which electrically connect the first channel layers CL1, the second bonding pads BP2, and the third bonding pads BP3 to each other. The second connection conductors CB2 may include second contacts CT2, second lines ML2, third contacts CT3, a fourth contact CT4, first bit line contacts BCT1, a first bit line BL1, fifth contacts CT5, a third line ML3, and sixth contacts CT6.

The second contact CT2 of the second connection conductors CB2 may be connected to the second bonding pad BP2. The second contact CT2 of the second connection conductors CB2 may be in contact with the second bonding pad BP2. The second contacts CT2 may be provided in the third insulating layer 130.

The third contacts CT3 may penetrate the first contact insulating structure CS1 while extending in the third direction D3. The fourth contact CT4 may penetrate the second stack structure STA2 while extending in the third direction D3. The second line ML2 may connect the third contact CT3 and the second contact CT2 or connect the fourth contact CT4 and the second contact CT2. The second lines ML2 may be provided in the third insulating layer 130.

The first channel layer CL1 may be connected to the first bit line contact BCT1 of the second connection conductors CB2. The first channel layer CL1 may be in contact with the first bit line contact BCT1 of the second connection conductors CB2. The first bit line contact BCT1 may be connected to the first bit line BL1. The third line ML3 may be provided at substantially the same level as the first bit line BL1. The third line ML3 and the first bit line BL1 may be provided in the sixth insulating layer 160. The fifth contact CT5 may connect the first bit line BL1 and the third contact CT3 or connect the third line ML3 and the fourth contact CT4. The fifth contacts CT5 may be provided in the sixth insulating layer 160.

The semiconductor device may include a first bit line (not shown) and a fifth contact (not shown). The third contact CT3 which is not connected to the fifth contact CT5 may be connected to the first bit line (not shown) through the fifth contact (not shown).

The third bonding pad BP3 may be connected to the sixth contact CT6 of the second connection conductors CB2. The third bonding pad BP3 may be in contact with the sixth contact CT6 of the second connection conductors CB2. The sixth contact CT6 may connect the first bit line BL1 and the third bonding pad BP3 or connect the third line ML3 and the third bonding pad BP3. The sixth contacts CT6 may be provided in the seventh insulating layer 170.

Each of the second contacts CT2, the second lines ML2, the third contacts CT3, the fourth contact CT4, the first bit line contacts BCT1, the first bit line BL1, the fifth contacts CT5, the third line ML3, and the sixth contacts CT6 may include a conductive layer and a barrier layer. In an example, the conductive layer may include copper, aluminum, or tungsten. In an example, the barrier layer may include titanium, tantalum, titanium nitride, or tantalum nitride.

A fourth connection structure CNS4 may be provided on the third connection structure CNS3. The fourth connection structure CNS4 may include an eighth insulating layer 180 and fourth bonding pads BP4.

The eighth insulating layer 180 may cover the seventh insulating layer 170. The eighth insulating layer 180 may include an insulating material. The eighth insulating layer 180 may include oxide or nitride.

The fourth bonding pads BP4 may be provided in the eighth insulating layer 180. The fourth bonding pad BP4 will be described in detail with reference to FIG. 1C.

A second semiconductor structure SEM2 may be provided on the fourth connection structure CNS4. The second semiconductor structure SEM2 may include a ninth insulating layer 190, second source layers SA2, a third stack structure STA3, a fourth stack structure STA4, a second contact insulating structure CS2, a second slit structure SLS2, second channel layers CL2, second memory layers MR2, second filling layers FI2, and a tenth insulating layer 210.

The ninth insulating layer 190 may cover the eighth insulating layer 180. The ninth insulating layer 190 may include an insulating material. In an example, the ninth insulating layer 190 may include oxide or nitride.

The second source layers SA2 may be provided in the ninth insulating layer 190. The second source layer SA2 may have the shape of a plate extending along a plane defined by the first direction D1 and the second direction D2. The second source layers SA2 may be spaced apart from each other in the first direction D1. A portion of the ninth insulating layer 190 may be interposed between the second source layers SA2 spaced apart from each other. The second source layer SA2 may include a conductive material. In an example, the second source layer SA2 may include poly-silicon. The second source layer SA2 may be provided in the cell region CER.

The third stack structure STA3 may be provided on the second source layers SA2. The third stack structure STA3 may include second conductive patterns CP2 and fourth insulating patterns IP4, which are alternately stacked in the third direction D3. The second conductive patterns CP2 may be used as word lines or select lines of the semiconductor device. The second conductive patterns CP2 may include a conductive material. The fourth insulating patterns IP4 may include an insulating material. In an example, the fourth insulating patterns IP4 may include oxide. The third stack structure STA3 may be provided in the cell region CER.

The second memory layers MR2, the second channel layers CL2, and the second filling layers FI2 may penetrate the third stack structure STA3. The second memory layers MR2, the second channel layers CL2, and the second filling layers FI2 may extend in the third direction D3. The second channel layer CL2 may surround the second filling layer FI2, and the second memory layer MR2 may surround the second channel layer CL2. The second channel layers CL2 may be in contact with the second source layer SA2.

The second filling layer FI2 may include an insulating material. In an example, the second filling layer FI2 may include oxide. The second channel layer CL2 may include a semiconductor material. In an example, the second channel layer CL2 may include poly-silicon. The second memory layer MR2 may include a tunnel insulating layer surrounding the second channel layer CL2, a data storage layer surrounding the tunnel insulating layer, and a blocking layer surrounding the data storage layer.

The fourth stack structure STA4 may be provided on the ninth insulating layer 190. The fourth stack structure STA4 may be provided at substantially the same level as the third stack structure STA3. The fourth stack structure STA4 may include fifth insulating patterns IP5 and sixth insulating patterns IP6, which are alternately stacked in the third direction D3. The fifth insulating patterns IP5 of the fourth stack structure STA4 may be disposed at substantially the same level as the second conductive patterns CP2 of the third stack structure STA3. The fifth insulating patterns IP5 may include an insulating material. In an example, the fifth insulating patterns IP5 may include nitride. The sixth insulating patterns IP6 of the fourth stack structure STA4 may be disposed at substantially the same level as the fourth insulating patterns IP4. The sixth insulating patterns IP6 of the fourth stack structure STA4 may include the same material as the fourth insulating patterns IP4 of the third stack structure STA3. In an example, the sixth insulating patterns IP6 may include oxide. The sixth insulating patterns IP6 of the fourth stack structure STA4 and the fourth insulating patterns IP4 of the third stack structure STA3 may be continuously formed without any boundary. The fourth stack structure STA4 may be provided in the connection region COR.

The third and fourth bonding pads BP3 and BP4 may be provided between the third and fourth stack structures STA3 and STA4 and the first and second stack structures STA1 and STA2. The first and second stack structures STA1 and STA2 may be provided under the third and fourth bonding pads BP3 and BP4. The third and fourth stack structures STA3 and STA4 may be provided above the third and fourth bonding pads BP3 and BP4.

The tenth insulating layer 210 may cover the third stack structure STA3 and the fourth stack structure STA4. The tenth insulating layer 210 may include an insulating material. In an example, the tenth insulating layer 210 may include oxide or nitride.

The second contact insulating structure CS2 may have the shape of a slit extending in the second direction D2 and the third direction D3. The second contact insulating structure CS2 may penetrate the tenth insulating layer 210 and the third stack structure STA3 in the third direction D3. A bottom surface of the second contact insulating structure CS2 may be in contact with a top surface of the ninth insulating layer 190. The second contact insulating structure CS2 may be disposed between the second source layers SA2. The second contact insulating structure CS2 may include an insulating material. In an example, the second contact insulating structure CS2 may include oxide or nitride.

The second slit structure SLS2 may have the shape of a slit extending in the second direction D2 and the third direction D3. The second slit structure SLS2 may penetrate the tenth insulating layer 210 and the third stack structure STA3 in the third direction D3. A bottom surface of the second slit structure SLS2 may be in contact with a top surface of the second source layer SA2. The second slit structure SLS2 may include an insulating material. In an example, the second slit structure SLS2 may include oxide or nitride.

A fifth connection structure CNS5 may be provided on the second semiconductor structure SEM2. The fifth connection structure CNS5 may include an eleventh insulating layer 220, a twelfth insulating layer 230, and fourth lines ML4.

The eleventh insulating layer 220 may cover the tenth insulating layer 210. The eleventh insulating layer 220 may cover a top surface of the second contact insulating structure CS2 and a top surface of the second slit structure SLS2. The eleventh insulating layer 220 may include an insulating material. In an example, the eleventh insulating layer 220 may include oxide or nitride.

The twelfth insulating layer 230 may cover the eleventh insulating layer 220. The twelfth insulating layer 230 may include an insulating material. In an example, the twelfth insulating layer 230 may include oxide or nitride.

The fourth lines ML4 may be provided in the twelfth insulating layer 230. The fourth lines ML4 may include a conductive material. In an example, the fourth lines ML4 may include aluminum.

Third connection conductors CB3 may be provided, which electrically connect the second channel layers CL2, the fourth bonding pads BP4, and the fourth lines ML4 to each other. The third connection conductors CB3 may include seventh contacts CT7, fifth lines ML5, eighth contacts CT8, a ninth contact CT9, second bit line contacts BCT2, a second bit line BL2, tenth contacts CT10, sixth lines ML6, and eleventh contacts CT11.

The seventh contact CT7 of the third connection conductors CB3 may be connected to the fourth bonding pad BP4. The seventh contact CT7 of the third connection conductors CB3 may be in contact with the fourth bonding pad BP4. The seventh contacts CT7 may be provided in the eighth insulating layer 180.

The eighth contacts CT8 may penetrate the second contact insulating structure CS2 while extending in the third direction D3. The ninth contact CT9 may penetrate the fourth stack structure STA4 while extending in the third direction D3. The fifth line ML5 may connect the eighth contact CT8 and the seventh contact CT7 or connect the ninth contact CT9 and the seventh contact CT7. The fifth lines ML5 may be provided in the eighth insulating layer 180.

The second channel layer CL2 may be connected to the second bit line contact BCT2 of the third connection conductors CB3. The second channel layer CL2 may be in contact with the second bit line contact BCT2 of the third connection conductors CB3. The second bit line contact BCT2 may be connected to the second bit line BL2. The sixth lines ML6 may be provided at substantially the same level as the second bit line BL2. The sixth lines ML6 and the second bit line BL2 may be provided in the eleventh insulating layer 220. The tenth contact CT10 may connect the second bit line BL2 and the eighth contact CT8 or connect the sixth line ML6 and the ninth contact CT9. The tenth contacts CT10 may be provided in the eleventh insulating layer 220.

The semiconductor layer may include a second bit line (not shown) and a tenth contact (not shown). The eight contact CT8 which is not connected to the tenth contact CT10 may be connected to the second bit line (not shown) through the tenth contact (not shown).

The fourth line ML4 may be connected to the eleventh contact CT11 of the third connection conductors CB3. The fourth line ML4 may be in contact with the eleventh contact CT11 of the third connection conductors CB3. The eleventh contact CT11 may connect the second bit line BL2 and the fourth line ML4 or connect the sixth line ML6 and the fourth line ML4. The eleventh contacts CT11 may be provided in the twelfth insulating layer 230.

Each of the seventh contacts CT7, the fifth lines ML5, the eighth contacts CT8, the ninth contact CT9, the second bit line contacts BCT2, the second bit line BL2, the tenth contacts CT10, the sixth line ML6, and the eleventh contacts CT11 may include a conductive layer and a barrier layer. In an example, the conductive layer may include copper, aluminum, or tungsten. In an example, the barrier layer may include titanium, tantalum, titanium nitride, or tantalum nitride.

Unlike as shown in the drawing, a number of the semiconductor structures SEM1 and SEM2 of the semiconductor device is not limited to 2. In an example, the number of the semiconductor structures SEM1 and SEM2 may be 3 or more. The channel layers CL1 and CL2 of the semiconductor structures SEM1 and SEM2 may be electrically connected to each other through the bonding pads BP1, BP2, PB3, and BP4 and the connection structures CB1, CB2, and CB3, respectively. The channel layers CL1 and CL2 of the semiconductor structures SEM1 and SEM2 may be electrically connected to the peripheral transistors TR through the bonding pads BP1, BP2, PB3, and BP4 and the connection structures CB1, CB2, and CB3.

Referring to FIG. 1B, the first bonding pad BP1 may include a conductive layer and a barrier layer. The conductive layer of the first bonding pad BP1 may be defined as a first conductive layer CO1. The barrier layer of the first bonding pad BP1 may be defined as a first barrier layer BR1. The first barrier layer BR1 may surround the first conductive layer CO1.

The second bonding pad BP2 may include a conductive layer and a barrier layer. The conductive layer of the second bonding pad BP2 may be defined as a second conductive layer CO2. The barrier layer of the second bonding pad BP2 may be defined as a second barrier layer BR2. The second barrier layer BR2 may surround the second conductive layer CO2.

A conductive layer of the first contact CT1 may be defined as a third conductive layer CO3. A barrier layer of the first contact CT1 may be defined as a third barrier layer BR3. A conductive layer of the second contact CT2 may be defined as a fourth conductive layer CO4. A barrier layer of the second contact CT2 may be defined as a fourth barrier layer BR4.

The first conductive layer CO1 of the first bonding pad BP1 and the second conductive layer CO2 of the second bonding pad BP2 may include different metal materials. In an example, the first conductive layer CO1 may include copper, and the second conductive layer CO2 may include tungsten. In an example, the first and second barrier layers BR1 and BR2 may include titanium, tantalum, titanium nitride, or tantalum nitride.

The metal material which the first conductive layer CO1 of the first bonding pad BP1 includes may have a resistance lower than that of the metal material which the second conductive layer CO2 of the second bonding pad BP2 includes. At the same temperature, the metal material which the second conductive layer CO2 of the second bonding pad BP2 includes may have a diffusion coefficient smaller than that of the metal material which the first conductive layer CO1 of the first bonding pad BP1 includes.

The first barrier layer BR1 may cover a bottom surface CO1_B and a sidewall CO1_S of the first conductive layer CO1. The second barrier layer BR2 may cover a bottom surface CO2_B and a sidewall CO2_S of the second conductive layer CO2.

The second barrier layer BR2 may be in contact with a top surface CO1_T of the first conductive layer CO1. The third insulating layer 130 may be in contact with the top surface CO1_T of the first conductive layer CO1. The second conductive layer CO2 may be spaced apart from the first conductive layer CO1. The first barrier layer BR1 may be spaced apart from the second barrier layer BR2 and the second conductive layer CO2.

The fourth barrier layer BR4 of the second contact CT2 may be in contact with a top surface CO2_T of the second conductive layer CO2 of the second bonding pad BP2. The fourth conductive layer CO4 of the second contact CT2 may be spaced apart from the second conductive layer CO2 of the second bonding pad BP2. The third conductive layer CO3 of the first contact CT1 may be in contact with the first barrier layer BR1 of the first bonding pad BP1. The third conductive layer CO3 of the first contact CT1 may be spaced apart from the first conductive layer CO1 of the first bonding pad BP1.

A width of the first bonding pad BP1 in the first direction D1 may be defined as a first width W1. A width of the second bonding pad BP2 in the first direction D1 may be defined as a second width W2. The first width W1 of the first bonding pad BP1 may become smaller in the direction toward the first contact CT1. The first width W1 of the first bonding pad BP1 may become smaller in the direction away from the second bonding pad BP2. The first width W1 of the first bonding pad BP1 may decrease with increasing distance from the second bonding pad BP2. In other words, a section (e.g., a section shown in FIG. 1B) of the first bonding pad BP1 may have the shape of a trapezoid.

The second width W2 of the second bonding pad BP2 may become smaller in the direction toward the first bonding pad BP1. The second width W2 of the second bonding pad BP2 may decrease with decreasing distance to the first bonding pad BP1. In other words, a section (e.g., a section shown in FIG. 1B) of the second bonding pad BP2 may have the shape of a trapezoid. The first width W1 of the first bonding pad BP1 may be greater than the second width W2 of the second bonding pad BP2.

Referring to FIG. 1C, the third bonding pad BP3 may include a conductive layer and a barrier layer. The conductive layer of the third bonding pad BP3 may be defined as a fifth conductive layer CO5. The barrier of the third bonding pad BP3 may be defined as a fifth barrier layer BR5. The fifth barrier layer BR5 may surround the fifth conductive layer CO5.

The fourth bonding pad BP4 may include a conductive layer and a barrier layer. The conductive layer of the fourth bonding pad BP4 may be defined as a sixth conductive layer CO6. The barrier layer of the fourth bonding pad BP4 may be defined as a sixth barrier layer BR6. The sixth barrier layer BR6 may surround the sixth conductive layer CO6.

A conductive layer of the sixth contact CT6 may be defined as a seventh conductive layer CO7. A barrier layer of the sixth contact CT6 may be defined as a seventh barrier layer BR7. A conductive layer of the seventh contact CT7 may be defined as an eighth conductive layer CO8. A barrier layer of the seventh contact CT7 may be defined as an eighth barrier layer BR8.

The fifth conductive layer CO5 of the third bonding pad BP3 and the sixth conductive layer CO6 of the fourth bonding pad BP4 may include different metal materials. In an example, the fifth conductive layer CO5 may include copper, and the sixth conductive layer CO6 may include tungsten. In an example, the fifth and sixth barrier layers BR5 and BR6 may include titanium, tantalum, titanium nitride, or tantalum nitride.

The metal material which the fifth conductive layer CO5 of the third bonding pad BP3 includes may have a resistance lower than that of the metal material which the sixth conductive layer CO6 of the fourth bonding pad BP4 includes. At the same temperature, the metal material which the sixth conductive layer CO6 of the fourth bonding pad BP4 includes may have a diffusion coefficient smaller than that of the metal material which the fifth conductive layer CO5 of the third bonding pad BP3 includes.

The fifth barrier layer BR5 may cover a bottom surface CO5_B and a sidewall CO5_S of the fifth conductive layer CO5. The sixth barrier layer BR6 may cover a bottom surface CO6_B and a sidewall CO6_S of the sixth conductive layer CO6.

The sixth barrier layer BR6 may be in contact with a top surface CO5_T of the fifth conductive layer CO5. The eighth insulating layer 180 may be in contact with the top surface CO5_T of the fifth conductive layer CO5. The sixth conductive layer CO6 may be spaced apart from the fifth conductive layer CO5. The fifth barrier layer BR5 may be spaced apart from the sixth barrier layer BR6 and the sixth conductive layer CO6.

The eighth barrier layer BR8 of the seventh contact CT7 may be in contact with a top surface CO6_T of the sixth conductive layer CO6. The eighth conductive layer CO8 of the seventh contact CT7 may be spaced apart from the sixth conductive layer CO6 of the fourth bonding pad BP4. The seventh conductive layer CO7 of the sixth contact CT6 may be in contact with the fifth barrier layer BR5 of the third bonding pad BP3. The seventh conductive layer CO7 of the sixth contact CT6 may be spaced apart from the fifth conductive layer CO5 of the third bonding pad BP3.

A width of the third bonding pad BP3 in the first direction D1 may be defined as a third width W3. A width of the fourth bonding pad BP4 in the first direction D1 may be defined as a fourth width W4. The third width W3 of the third bonding pad BP3 may become smaller in the direction toward the sixth contact CT6. The third width W3 of the third bonding pad BP3 may decrease with decreasing distance to the sixth contact CT6. The third width W3 of the third bonding pad BP3 may become smaller in the direction away from the fourth bonding pad BP4. The third width W3 of the third bonding pad BP3 may decrease with increasing distance from the fourth bonding pad BP4. In other words, a section (e.g., a section shown in FIG. 1C) of the third bonding pad BP3 may have the shape of a trapezoid.

The fourth width W4 of the fourth bonding pad BP4 may become smaller in the direction toward the third bonding pad BP3. The fourth width W4 of the fourth bonding pad BP4 may decrease with decreasing distance to the third bonding pad BP3. In other words, a section (e.g., a section shown in FIG. 1C) of the fourth bonding pad BP4 may have the shape of a trapezoid. The third width W3 of the third bonding pad BP3 may be greater than the fourth width W4 of the fourth bonding pad BP4.

In the semiconductor device in accordance with the embodiment of the present disclosure, the second barrier layer BR2 of the second bonding pad BP2 is disposed between the second conductive layer CO2 and the first conductive layer CO1 of the first bonding pad BP1, so that a metal bonding structure can be formed even when the first conductive layer CO1 of the first bonding pad BP1 and the second conductive layer CO2 of the second bonding pad BP2 include different metal materials. For example, the first bonding pad BP1 including copper and the second bonding pad BP2 including tungsten may be bonded to each other.

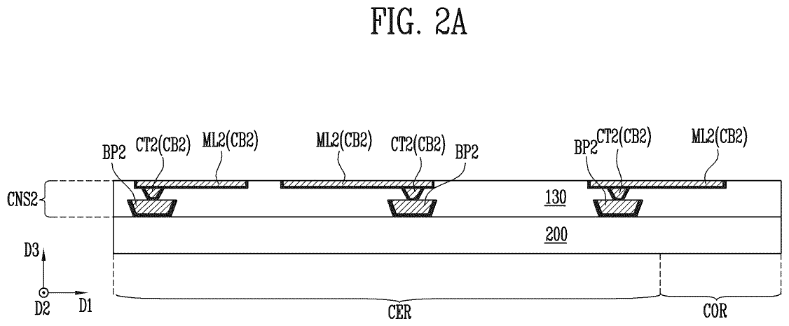

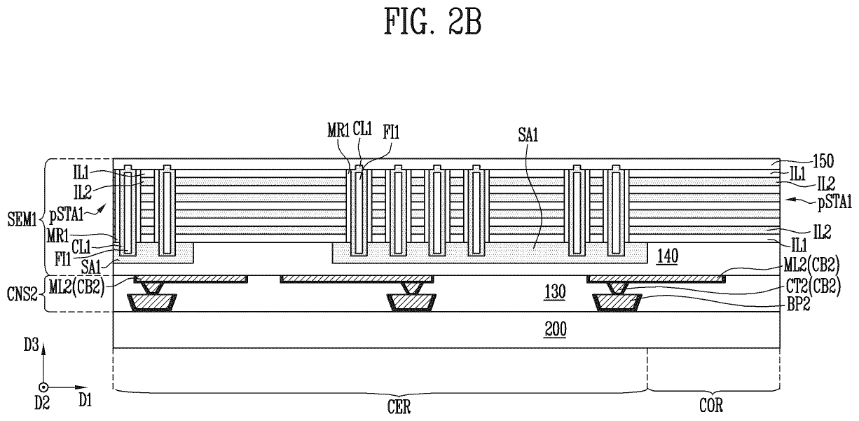

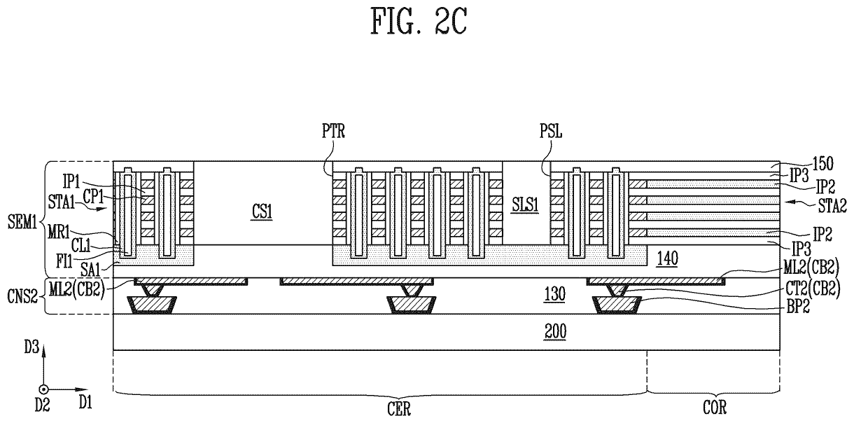

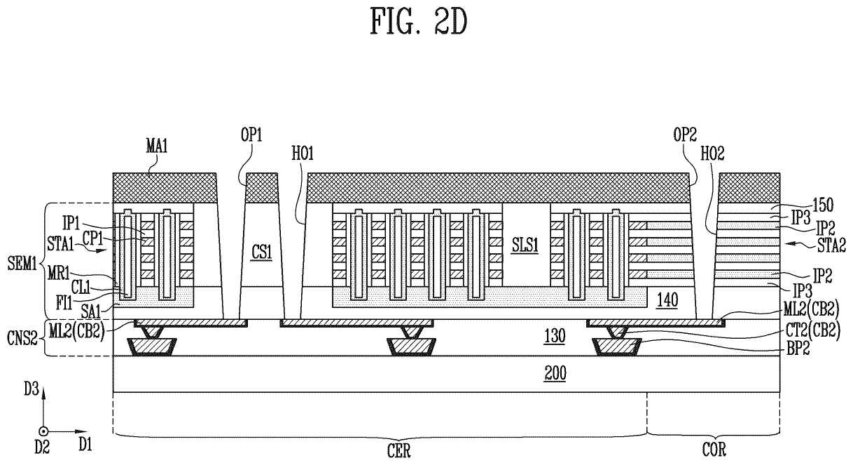

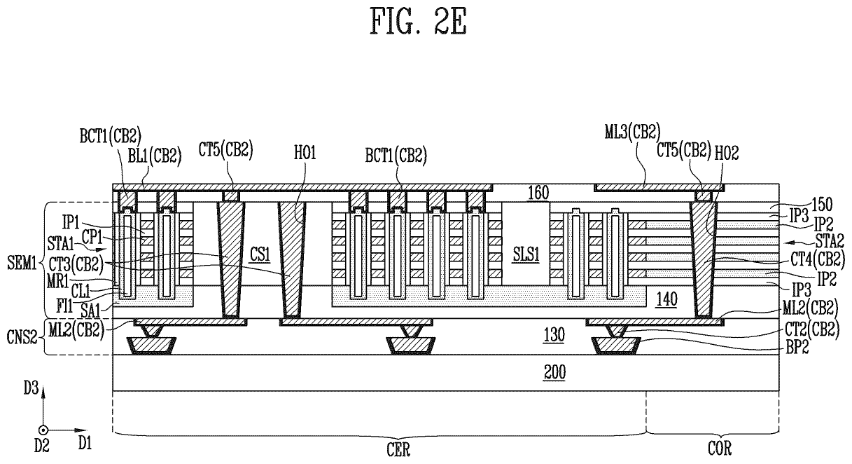

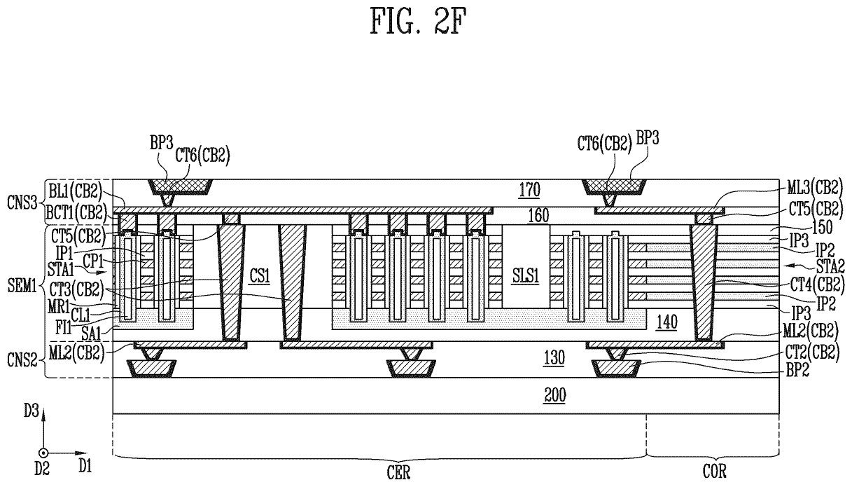

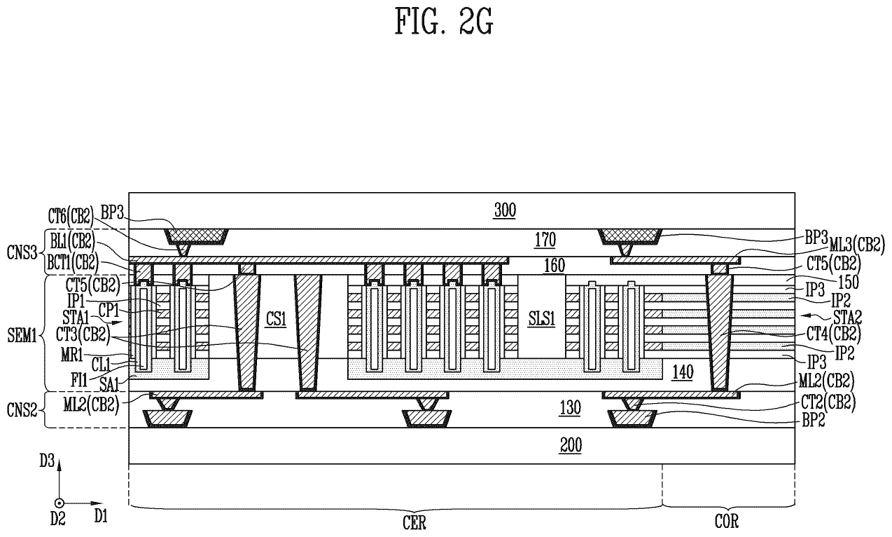

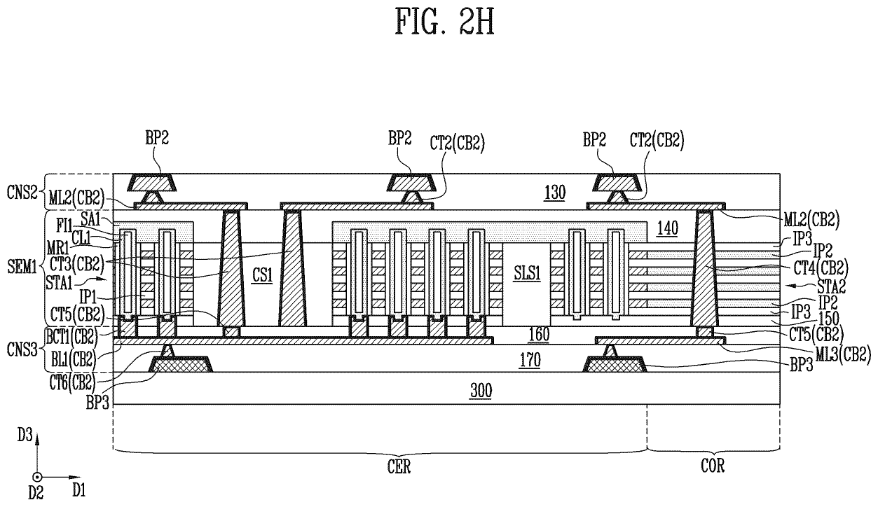

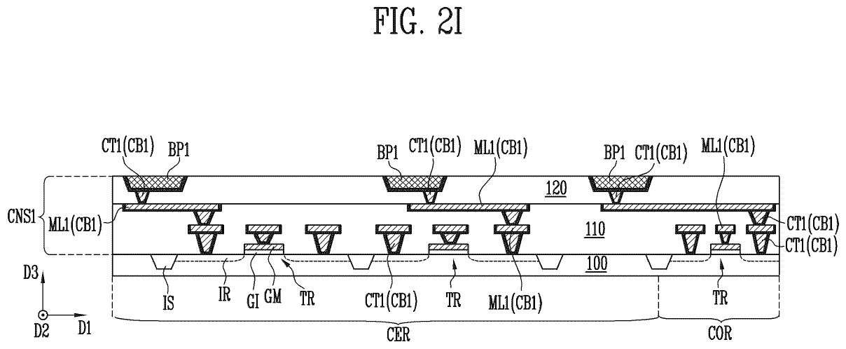

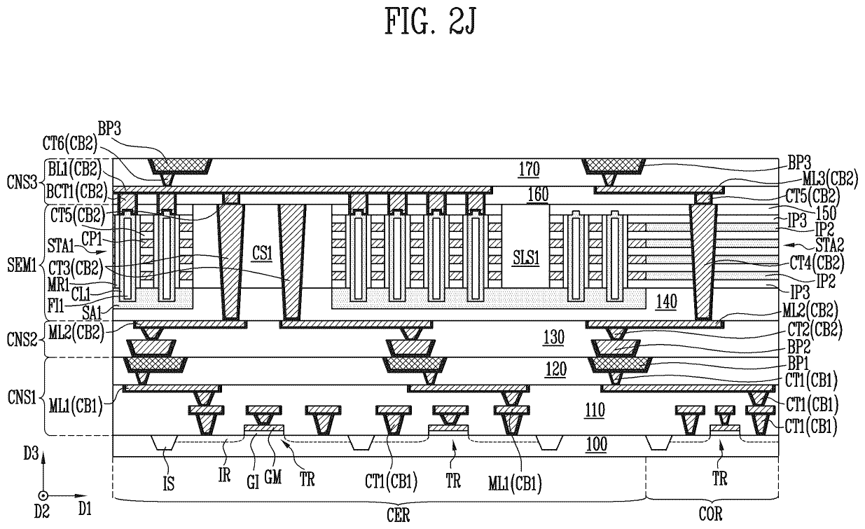

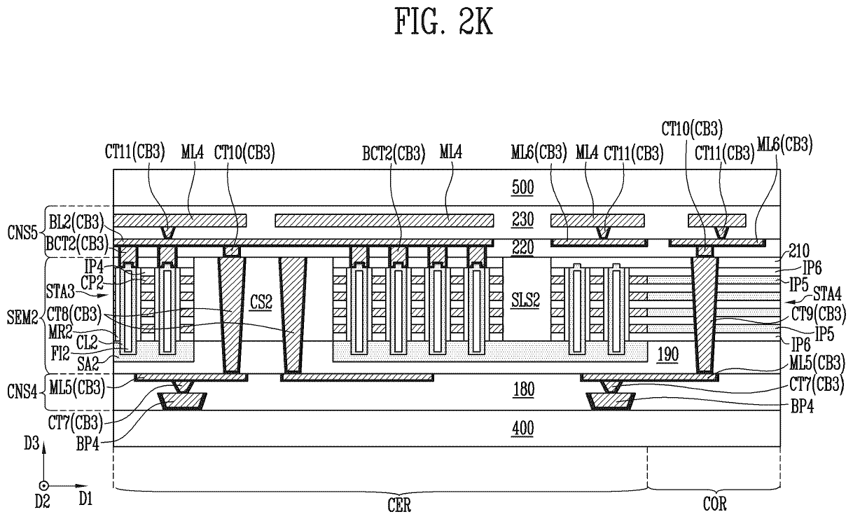

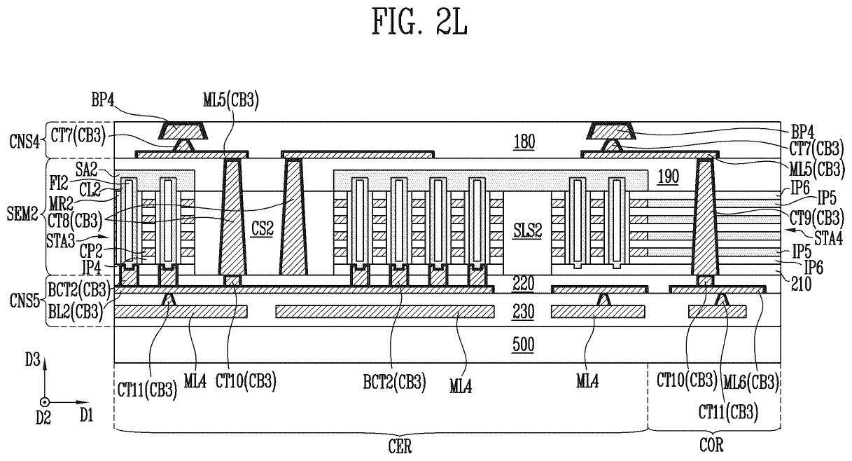

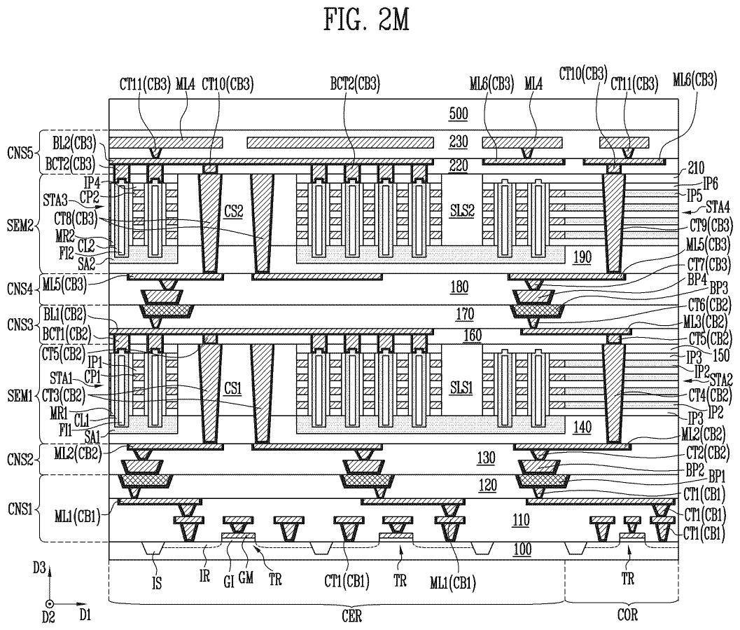

FIGS. 2A, 2B, 2C, 2D, 2E, 2F, 2G, 2H, 2I, 2J, 2K, 2L, and 2M are sectional views illustrating a manufacturing method of the semiconductor device shown in FIGS. 1A to 1C.

For convenience of description, repeated descriptions of the components described with reference to FIGS. 1A to 1C will be omitted.

The manufacturing method described below is merely one embodiment of a manufacturing method of the semiconductor device shown in FIGS. 1A to 1C, and the manufacturing method of the semiconductor device shown in FIGS. 1A to 1C is not limited to that described below.

Referring to FIG. 2A, a second substrate 200 and a second connection structure CNS2 may be formed.

The second substrate 200 may have the shape of a plane extending along a plane defined by the first direction D1 and the second direction D2. The second substrate 200 may be a semiconductor substrate. In an example, the second substrate 200 may be a silicon substrate.

The second connection structure CNS2 may be formed on the second substrate 200. A third insulating layer 130 may be formed on the substrate 200. Second bonding pads BP2, second contacts CT2, and second lines ML2 may be formed in the third insulating layer 130.

Referring to FIG. 2B, a first semiconductor structure SEM1 may be formed on the second connection structure CNS2. The forming of the first semiconductor structure SEM1 may include forming a fourth insulating layer 140 on the third insulating layer 130; forming first source layers SA1 in the fourth insulating layer 140; forming a first preliminary stack structure pSTA1 on the fourth insulating layer 140 and the first source layers SA1; forming a first filling layer FI1, a first channel layer CL1, and a first memory layer MR1, in the first preliminary stack structure pSTA1; and forming a fifth insulating layer 150 on the first preliminary stack structure pSTA1.

The first preliminary stack structure pSTA1 may include a first stack insulating layer IL1 and a second stack insulating layer IL2, which are alternately stacked in the third direction D3. The first and second stack insulating layers IL1 and IL2 may include different insulating materials. In an example, the first stack insulating layer IL1 may include oxide, and the second stack insulating layer IL2 may include nitride.

When the first semiconductor structure SEM1 is formed on the second connection structure CSN2, second conductive layers CO2 (see FIG. 1B) of the second bonding pads BP2 may include a metal material which allows migration or diffusion to be reduced or minimized in a thermal process of forming the first source layers SA1 of the first semiconductor structure SEM1, first bit lines BL1, and the first channel layers CL1. In an example, the second conductive layers CO2 of the second bonding pads BP2 may include tungsten.

Referring to FIG. 2C, first conductive patterns CP1, a first contact insulating structure CS1, and a first slit structure SLS1 may be formed.

A penetrating trench PTR and a penetrating slit PSL may be formed, which penetrate the first preliminary stack structure pSTA1. The second stack insulating layers IL2 exposed through the penetrating trench PTR and a penetrating slit PSL may be etched. When the second stack insulating layers IL2 are etched, a portion of each second stack insulating layers IL2, which is disposed in a cell region CER, may be removed. Subsequently, the first conductive patterns CP1 may be formed in empty spaces formed by removing the portions of the second stack insulating layers IL2, which are disposed in the cell region CER. After the first conductive patterns CP1 are formed, the first contact insulating structure CS1 may be formed in the penetrating trench PTR, and the first slit structure SLS1 may be formed in the penetrating slit PSL.

When the second stack insulating layers IL2 are etched, a portion of each of the second stack insulating layers IL2, which is disposed in a connection region COR, may remain. The remaining portions of the second stack insulating layers IL2 may be defined as second insulating patterns IP2.

When the first conductive patterns CP1 are formed, portions of the first stack insulating layers IL1, which overlap with the first conductive patterns CP1, may be defined as first insulating patterns IP1, and portions of the first stack insulating layers IL1, which overlap with the second insulating patterns IP2, may be defined as third insulating patterns IP3.

When the first conductive patterns CP1 are formed, a first stack structure STA1 may be formed, which includes the first conductive patterns CP1 and the first insulating patterns IP1, and a second stack structure STA2 may be formed, which includes the second insulating patterns IP2 and the third insulating patterns IP3.

Referring to FIG. 2D, first holes HO1 may be formed, which penetrate the first contact insulating structure CS1, and a second hole HO2 may be formed, which penetrates the second stack structure STA2.

The forming of the first holes HO1 and the second hole HO2 may include forming a first mask layer MA1 on the fifth insulating layer 150 of the first semiconductor structure SEM1, forming first openings OP1 and a second opening OP2 in the first mask layer MA1, etching the first contact insulating structure CS1 through the first openings OP1, and etching the second stack structure STA2 through the second opening OP2.

When the first holes HO1 are formed, the second lines ML2 under the first contact insulating structure CS1 may be exposed. When the second hole HO2 is formed, the second line ML2 under the second stack structure STA2 may be exposed. After the first and second holes HO1 and HO2 are formed, the first mask layer MA1 may be removed.

Referring to FIG. 2E, third contacts CT3 may be formed, which penetrate the first contact insulating structure CS1. The third contacts CT3 may be respectively formed in the first holes HO1. A fourth contact CT4 may be formed, which penetrates the second stack structure STA2. The fourth contact CT4 may be formed in the second hole HO2. After the third and fourth contacts CT3 and CT4 are formed, a sixth insulating layer 160 may be formed on the first semiconductor structure SEM1.

Subsequently, a first bit line contact BCT1 may be formed, which is connected to the first channel layer CL1. Fifth contacts CT5 may be formed, which are connected to the third and fourth contacts CT3 and CT4. Subsequently, a first bit line BL1 and a third line ML3 may be formed.

Referring to FIG. 2F, a seventh insulating layer 170 may be formed on the sixth insulating layer 160. Subsequently, sixth contacts CT6 and third bonding pads BP3 may be formed. When the seventh insulating layer 170 and the third bonding pads BP3 are formed, a third connection structure CNS3 may be formed on the first semiconductor structure SEM1. Second connection conductors CB2 may electrically connect the first channel layers CL1, the second bonding pads BP2, and the third bonding pads BP3 to each other.

When the third connection structure CNS3 is formed after the first semiconductor structure SEM1 is formed, it is unnecessary for fifth conductive layers CO5 (see FIG. 1C) of the third bonding pads BP3 to use any metal material which allows migration or diffusion to be reduced or minimized in a thermal process, and hence a metal material can be selected without limitation. Accordingly, the fifth conductive layers CO5 of the third bonding pads BP3 can use a metal material having a relatively low resistance. The metal material which the fifth conductive layers CO5 of the third bonding pads BP3 include may have a resistance lower than that which the second conductive layers CO2 (see FIG. 1B) of the second bonding pads BP2 include. In an example, the fifth conductive layers CO5 of the third bonding pads BP3 may include copper.

At the same temperature, a diffusion coefficient of the metal material which the second conductive layers CO2 of the second bonding pads BP2 include may be smaller than that of the metal material which the fifth conductive layers CO5 of the third bonding pads BP3 include.

Referring to FIG. 2G, a third substrate 300 may be formed on the third connection structure CNS3. The third substrate 300 may have the shape of a plate extending along a plane defined by the first direction D1 and the second direction D2. The third substrate 300 may be a semiconductor substrate. In an example, the third substrate 300 may be a silicon substrate.

Referring to FIG. 2H, the second substrate 200, the second connection structure CNS2, the first semiconductor structure SEM1, the third connection structure CNS3, and the third substrate 300 may be reversed. When the second substrate 200, the second connection structure CNS2, the first semiconductor structure SEM1, the third connection structure CNS3, and the third substrate 300 are reversed, the second substrate 200 may be disposed on the second connection structure CNS2 including the second bonding pads BP2.

Subsequently, the second substrate 200 may be removed. In an example, the second substrate 200 may be removed through chemical mechanical polishing (CMP) or an etching process. When the second substrate 200 is removed, second barrier layers BR2 (see FIG. 1B) of the second bonding pads BP2 may be exposed.

Referring to FIG. 2I, an isolation layer IS may be formed in a first substrate 100, and peripheral transistors TR may be formed on the first substrate 100. Subsequently, a first connection structure CNS1 may be formed on the first substrate 100. The forming of the first connection structure CNS1 may include forming a first insulating layer 110 and a second insulating layer 120 on the first substrate 100, and forming first contacts CT1, first line ML1, and first bonding pads BP1 in the first insulating layer 110 and the second insulating layer 120.

When the first connection structure CNS1 is formed on the first substrate 100, it is unnecessary for first conductive layers CO1 (see FIG. 1B) of the first bonding pads BP1 to use any metal material which allows migration or diffusion to be reduced or minimized in a thermal process, and hence a metal material can be selected without limitation. Accordingly, the first conductive layers CO1 of the first bonding pads BP1 can include a metal material having a relatively low resistance. The metal material which the first conductive layers CO1 of the first bonding pads PB1 include may have a resistance lower than that of the metal material which the second conductive layers CO2 (see FIG. 1B) of the second bonding pads BP2 include. In an example, the first conductive layers CO1 of the first bonding pads BP1 may include copper.

At the same temperature, a diffusion coefficient of the metal material which the second conductive layers CO2 of the second bonding pads BP2 include may be smaller than that of the metal material which the first conductive layers CO1 of the first bonding pads BP1 include.

Referring to FIG. 2J, the first bonding pads BP1 of the first connection structure CNS1 and the second bonding pads BP2 of the second connection structure CNS2 may be bonded to each other. After the second connection structure CNS2, the first semiconductor structure SEM1, the third connection structure CNS3, and the third substrate 300 (see FIG. 2H) are reversed, the first and second bonding pads BP1 and BP2 may be bonded to each other. When the first and second bonding pads BP1 and BP2 are bonded to each other, the first channel layers CL1 may be electrically connected to the peripheral transistors TR through the second connection conductors CB2, the first to second bonding pads BP1 and BP2, and the first connection conductors CB1.

After the first and second bonding pads BP1 and BP2 are bonded to each other, the third substrate 300 may be removed. In an example, the third substrate 300 may be removed through chemical mechanical polishing (CMP) or an etching process. When the third substrate 300 is removed, fifth barrier layers BR5 (see FIG. 1C) and fifth conductive layers CO5 (see FIG. 1C) of the third bonding pads BP3 may be exposed.

Referring to FIG. 2K, a fourth connection structure CNS4, a second semiconductor structure SEM2, a fifth connection structure CNS5, third connection conductors CB3, and a fifth substrate 500 may be formed on a fourth substrate 400.

The fourth substrate 400 may have the shape of a plate extending along a plane defined by the first direction D1 and the second direction D2. The fourth substrate 400 may be a semiconductor substrate. In an example, the fourth substrate 400 may be a silicon substrate.

A method of forming the fourth connection structure CNS4 and the second semiconductor structure SEM2 may be similar to that of forming the second connection structure CNS2 and the first semiconductor structure SEM1.

When the second semiconductor structure SEM2 is formed on the fourth connection structure CNS4, sixth conductive layers CO6 (see FIG. 1C) of fourth bonding pads BP4 may include a metal material which allows migration or diffusion to be reduced or minimized in a thermal process of forming second source layers SA2 of the second semiconductor structure SEM2, second bit lines BL2, and second channel layers CL2. In an example, the sixth conductive layers CO6 of the fourth bonding pads BP4 may include tungsten.

The fifth connection structure CNS5 may be formed on the second semiconductor structure SEM2. The second channel layers CL2, the fourth bonding pads BP4, and fourth lines ML4 may be electrically connected to each other by forming the third connection conductors CB3.

The fifth substrate 500 may be formed on the fifth connection structure CNS5. The fifth substrate 500 may have the shape of a plate extending along a plane defined by the first direction D1 and the second direction D2. The fifth substrate 500 may be a semiconductor substrate. In an example, the fifth substrate 500 may be a silicon substrate.

Referring to FIG. 2L, the fourth substrate 400, the fourth connection structure CNS4, the second semiconductor structure SEM2, the fifth connection structure CNS5, and the fifth substrate 500 may be reversed. When the fourth substrate 400, the fourth connection structure CNS4, the second semiconductor structure SEM2, the fifth connection structure CNS5, and the fifth substrate 500 are reversed, the fourth substrate 400 may be disposed on the fourth connection structure CNS4 including the fourth bonding pads BP4.

Subsequently, the fourth substrate 400 may be removed. In an example, the fourth substrate 400 may be removed through chemical mechanical polishing (CMP) or an etching process. When the fourth substrate 400 is removed, sixth barrier layers BR6 (see FIG. 1C) of the fourth bonding pads BP4 may be exposed.

Referring to FIG. 2M, the third bonding pads BP3 of the third connection structure CNS3 and the fourth bonding pads BP4 of the fourth connection structure CNS4 may be bonded to each other. After the fourth connection structure CNS4, the second semiconductor structure SEM2, the fifth connection structure CNS5, and the fifth substrate 500 are reserved, the third and fourth bonding pads BP3 and BP4 may be bonded to each other. When the third and fourth bonding pads BP3 and BP4 are bonded to each other, the second channel layers CL2 and the fourth lines ML4 may be electrically connected to the first channel layers CL1 and the peripheral transistors TR through the third connection conductors CB3, the third and fourth bonding pads BP3 and BP4, the second connection conductors CB2, the first and second bonding pads BP1 and BP2, and the first connection conductors CB1.

Subsequently, the fifth substrate 500 may be removed. In an example, the fifth substrate 500 may be removed through chemical mechanical polishing (CMP) or an etching process.

In the manufacturing method of the semiconductor device in accordance with the embodiment of the present disclosure, the second conductive layers CO2 (see FIG. 1B) of the second bonding pads BP2 and the sixth conductive layers CO6 (see FIG. 1C) of the fourth bonding pads BP4 may include a metal material which allows migration or diffusion to be reduced or minimized in the thermal process, and therefore, the migration or diffusion is curtailed or does not occur in the process of forming the first semiconductor structure SEM1 or the second semiconductor structure SEM2.

In the manufacturing method of the semiconductor device in accordance with the embodiment of the present disclosure, the second bonding pads BP2 of the second connection structure CNS2 may be formed before the first semiconductor structure SEM1, and the third bonding pads BP3 of the third connection structure CNS3 may be formed after the first semiconductor structure SEM1. Because the second bonding pads BP2 are formed earlier than the first semiconductor structure SEM1, the process of forming the second and third bonding pads BP2 and BP3 can be simplified, and the limitation of the process of forming the second and third bonding pads BP2 and BP3 can be minimized.

In the manufacturing method of the semiconductor device in accordance with the embodiment of the present disclosure, the second bonding pads BP2 and the third bonding pads BP3 may be formed above/under the first semiconductor structure SEM1. The second bonding pads BP2 may be bonded to the first bonding pads BP1, and the third bonding pads BP3 may be bonded to the fourth bonding pads BP4 under the second semiconductor structure SEM2. As described above, in the manufacturing method of the semiconductor device in accordance with the embodiment of the present disclosure, bonding pads are formed above/under each semiconductor structure, so that a plurality of semiconductor structures can be continuously stacked.

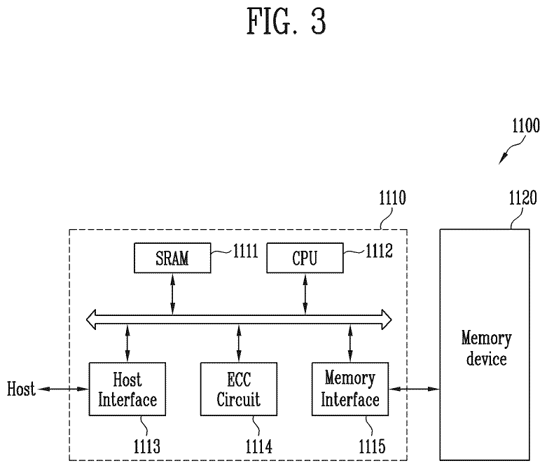

FIG. 3 is a block diagram illustrating a configuration of a memory system 1100 in accordance with an embodiment of the present disclosure.

Referring to FIG. 3, the memory system 1100 includes a memory device 1120 and a memory controller 1110.

The memory device 1120 may include the semiconductor device described above. The memory device 1120 may be a multi-chip package configured with a plurality of flash memory chips.

The memory controller 1110 is configured to control the memory device 1120, and may include Static Random Access Memory (SRAM) 1111, a Central Processing Unit (CPU) 1112, a host interface 1113, an Error Correction Code (ECC) circuit 1114, and a memory interface 1115. The SRAM 1111 is used as operation memory of the CPU 1112, the CPU 1112 performs overall control operations for data exchange of the memory controller 1110, and the host interface 1113 includes a data exchange protocol for a host connected with the memory system 1100. The ECC circuit 1114 detects and corrects an error included in a data read from the memory device 1120, and the memory interface 1115 interfaces with the memory device 1120. In addition, the memory controller 1110 may further include ROM for storing code data for interfacing with the host, and the like.

The memory system 1100 configured as described above may be a memory card or a Solid State Disk (SSD), in which the memory device 1120 is combined with the memory controller 1110. For example, when the memory system 1100 is an SSD, the memory controller 1110 may communicate with an external device (e.g., the host) through one of various interface protocols, such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA (SATA) protocol, a Parallel-ATA (PATA) protocol, a Small Computer System Interface (SCSI) protocol, an Enhanced Small Disk Interface (ESDI) protocol, and an Integrated Drive Electronics (IDE) protocol.

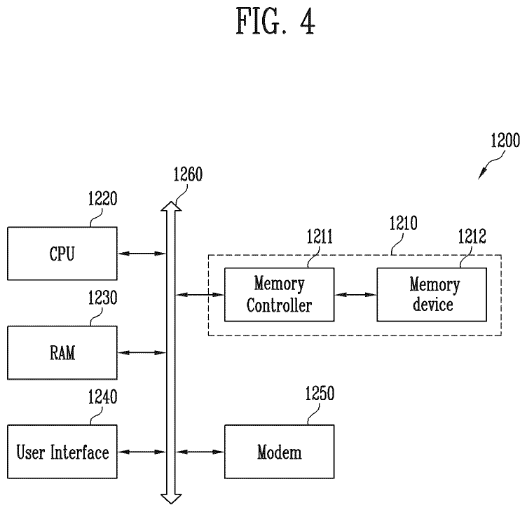

FIG. 4 is a block diagram illustrating a configuration of a computing system 1200 in accordance with an embodiment of the present disclosure.

Referring to FIG. 4, the computing system 1200 may include a CPU 1220, random access memory (RAM) 1230, a user interface 1240, a modem 1250, and a memory system 1210, which are electrically connected to a system bus 1260. When the computing system 1200 is a mobile device, a battery for supplying an operation voltage to the computing system 1200 may be further included, and an application chip set, a Camera Image Processor (CIS), a mobile D-RAM, and the like may be further included.

The memory system 1210 may be configured with a memory device 1212 and a memory controller 1211, which are similar to those described with reference to FIG. 3.

In the semiconductor device and the manufacturing method of the semiconductor device in accordance with the present disclosure, some of bonding pads connected to a channel layer are formed before the channel layer, so that process cost and process limitation for forming the bonding pads connected to the channel layer can be reduced or minimized.

Embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

So far as not being differently defined, all terms used herein including technical or scientific terminologies have meanings that they are commonly understood to have by those skilled in the art to which the present disclosure pertains. The terms having the definitions as defined in the dictionary should be understood such that they have meanings consistent with the context of the related technique. So far as not being clearly defined in this application, terms should not be understood in an ideally or excessively formal way.

What is claimed is:

1. A method of manufacturing a semiconductor device, the method comprising:
forming a first substrate;
forming a first connection structure including a first bonding pad on the first substrate;
forming a first semiconductor structure on the first connection structure, wherein the first semiconductor structure includes a first channel layer electrically connected to the first bonding pad and a first stack structure surrounding the first channel layer;
forming a second connection structure including a second bonding pad on the first semiconductor structure, wherein the second bonding pad is electrically connected to the first channel layer;
exposing the first bonding pad by removing the first substrate;
forming a third connection structure including a third bonding pad; and
bonding the first bonding pad and the third bonding pad to each other.

2. The method of claim 1, wherein the third bonding pad is electrically connected to a peripheral transistor.

3. The method of claim 1, wherein:
the first bonding pad includes a first conductive layer and a first barrier layer surrounding the first conductive layer, and
the first conductive layer includes tungsten.

4. The method of claim 3, wherein:
the second bonding pad includes a second conductive layer and a second barrier layer surrounding the second conductive layer, and
the second conductive layer includes copper.

5. The method of claim 3, wherein;
the third bonding pad includes a third conductive layer and a third barrier layer surrounding the third conductive layer, and
the third conductive layer includes copper.

6. The method of claim 5, wherein:
the first barrier layer is in contact with the third conductive layer, and
the first conductive layer is spaced apart from the third conductive layer.

7. The method of claim 1, further comprising:
forming a second substrate;
forming a third connection structure including a fourth bonding pad on the second substrate;
forming a second semiconductor structure on the third connection structure, wherein the second semiconductor structure includes a second channel layer electrically connected to the fourth bonding pad and a second stack structure surrounding the second channel layer;
exposing the fourth bonding pad by removing the second substrate; and
bonding the fourth bonding pad and the second bonding pad to each other.

8. The method of claim 7, wherein:
the fourth bonding pad includes a fourth conductive layer and a fourth barrier layer surrounding the fourth conductive layer, and
the fourth conductive layer includes tungsten.
